(19) United States
(12) Patent Application Publication
(10) Pub. No.: US 2004/0209429 A1
(43) Pub. Date: Oct. 21, 2004

(54) Method of forming bit line contact

(75) Inventors: Chih-Ching Lin, Taoyuan (TW); Yi-Nan Chen, Taipei (TW)

Correspondence Address: QUINTERO LAW OFFICE, 1617 BROADWAY, 3RD FLOOR, SANTA MONICA, CA, 90404, US

(73) Assignee: Nanya Technology Corporation

(21) Appl. No.: 10/720,611

(22) Filed: Nov. 24, 2003

(30) Foreign Application Priority Data
Apr. 15, 2003 (TW) 92108633

(51) Int. Cl. H01L 21/8234

(52) U.S. Cl. 438/279

(57) ABSTRACT

A method of forming bit line contact. A substrate has device and peripheral contact areas, with the device area having transistors including a gate electrode, a doped region, and a pair of barrier spacers formed on opposing sidewalls of two adjacent gate electrodes. A dielectric layer is formed overlying the substrate, and a contact formed through the dielectric layer, exposing the doped region. Finally, a conductive layer is formed as a bit line contact plug to fill the bit line contact.

### BACKGROUND OF THE INVENTION

1. Field of the Invention

The present invention relates in general to a method of forming a contact structure. In particular, the present invention relates to a method of forming a bit line contact structure comprising a polysilicon spacer and a silicon nitride liner.

2. Description of the Related Art

As ICs become more compact, semiconductor design has reduced device dimensions. For example, 64 M DRAM process has shifted from 0.35 μm to 0.3 μm or less, and 128 M or 256 M DRAM process to less than 0.2 μm.

Self-aligned contact (SAC) process is often used to enhance conducting wire accuracy, but becomes more difficult as critical dimension (CD) reduces. For example, in filling processes of bit line contact with line width lower than 0.11 μm, the above mentioned bit line contact is lower than 0.038 μm of exposed drain area width, easily suffering bit line contact from open circuits or word-line/bit-line from short circuits when a conductive layer is formed, functions may be disabled, impacting product yield and cost.

FIGS. 1A˜1F show conventional self-aligned contact fabrication method resulting in bit line open circuits or word-line/bit-line short circuits.

First, FIG. 1A shows a substrate 10 having a transistor structure, an alternating arrangement of the drain 12/source 14 areas on the active area surface of substrate 10, with a gate electrode 20 between source 14 and drain 12 areas protruding from substrate 10. Gate electrode 20 has a multi-layer structure to meet several requirements, having a gate dielectric layer 21, a conductive layer 22, a metal silicide layer 23, and a hard mask layer 24. A silicon nitride spacer 25 is formed on the sidewalls of the gate electrode 20. With spacer 25 on the sidewalls of the gate electrode 20, the exposed drain area 12 widths between the adjacent spacers of the gate electrodes 20 are less than 0.038 μm if line width is minimized to about 0.11 μm.

Subsequently, a dielectric layer 30 and a photoresist pattern layer 60 are formed on substrate 10. In FIG. 1B, the photoresist pattern layer 60 has an open region 60a acting as subsequent bit line contact position.

Next, the exposed dielectric layer 30 on the open region 60a is removed, forming a dielectric layer contact when the bit line contact is exposed from drain area 12, and a conductive layer 22 is filled into the above mentioned dielectric layer contact acting as the bit line contact plug. FIGS. 1C˜1D show bit line contact occurring, resulting in open circuits. FIGS. 1E˜1F show word-line/bit-line occurring, resulting in short circuits.

FIG. 1C shows an etching mask using photoresist pattern layer 60, wherein the dielectric layer 30 is anisotropically etched and forms the dielectric contact 31 exposed from the drain area 12, the bit line contact. Nevertheless, as mentioned above, the exposed drain area 12 width is less than 0.038 μm only with line width as low as 0.11 μm, in addition, the dielectric contact 31 is deep, such that etching of the dielectric layer 30 at the bottom of the dielectric contact 31 is more difficult when the dielectric layer 30 is close to the drain areas 12. After the above anisotropic etching, the incompletely or unetched dielectric layer 30 normally remains at the dielectric contact 31 bottom, resulting in the drain areas 12 not being exposed.

In FIG. 1D, barrier layer 40 is formed within the dielectric contact 31, and a conductive layer 50 is filled to act as bit line connection, when the dielectric layer 30 is not a conductor, such that conductive layer 50 and drain areas 12 are not electrically connected, resulting in the described bit line contact open circuits.

In order to prevent open circuits, a conventional method uses a lower etching selectivity of self-aligned contact (SAC) process parameters to perform the contact etching process, however, in the process designs of forming the bit line contact, in order to prevent short circuits between the gate electrode 20 (as the bit line) and subsequent bit line, in the gate electrode 20, the conductive polysilicon layer 22 and the metal silicide layer 23 are protected by hard mask layer 24 and sidewall spacer 25, then etched by high etching selectivity method to prevent their being exposed and connecting to subsequent bit line, with resulting short circuits. However, as etching selectivity for removal of the dielectric layer 30 located at bottom of the dielectric window 31a decreases, not only is the dielectric window 31a width increased, but also a portion of the hard mask 24 and spacer 25 is removed, forming the spacer 25a, exposing metal silicide layer 23, or even polysilicon layer 22.

FIG. 1F, when the conductive metal silicide layer 23 of the gate electrode 20 is exposed, once a barrier layer 40 is formed on the dielectric contact 31′, and the conductive layer 50 is filled to connect with the bit line, the conductive layer 50 and the metal silicide layer 23 become electrically connected, resulting in the mentioned bit-line/word-line short circuits.

In conventional implementation, overetching is also utilized to prevent bit line contact from short circuits, however, during formation of bit line contact, the silicon nitride is generally employed as a hard mask 24 and sidewall spacer 25, with the silicon oxide as dielectric layer 30, such that etching selectivity of dielectric layer 30 to hard mask 24 and sidewall spacer 25 is around 10. Even so, such low etching selectivity also etches hard mask 24 and sidewall spacer 25, exposing polysilicon layer 22 and the metal silicide layer 23, resulting in word-line/bit-line short circuits.

### SUMMARY OF THE INVENTION

Accordingly, an object of the invention is to provide a method of forming bit line contact using barrier material with high etching selectivity as a spacer, whereby self-aligned bit line contact etching is performed. Bit line contact open circuits and word-line/bit-line short circuits are prevented when the subsequent conductive layer is filled into the bit line contact.

In order to achieve the above object, the invention provides a method of forming bit line contact, comprising providing a substrate having a plurality of transistors therein, each including a gate electrode and doping areas serving as drain and source, forming a pair of barrier spacers on the opposite sidewalls of the adjacent gate electrodes, forming a dielectric layer overlying the surface of the gate electrodes, barrier spacers and doping areas, and, using the barrier spacer and the doping areas as etch stop, etching a portion of the dielectric layer to form a bit line contact.

In the above method, the barrier spacer may be formed by a conformal barrier layer on the surface of the gate electrodes and the doping areas, followed by etching the barrier layer, such that the barrier layer forms a barrier spacer on the sidewalls of the gate electrodes, forming a mask layer to cover the retained barrier spacer, and removing the unmasked portion of the barrier spacer.

In the above method, before forming the dielectric layer, a liner layer may be formed on the surface of the gate electrodes, barrier spacers and doping areas.

The invention provides another method of forming bit line contact comprising providing a substrate having a plurality of transistors therein, each including a gate electrode and doping areas serving as drain and source, forming a polysilicon spacer on the sidewalls of the gate electrode, forming a mask layer to cover a portion of the polysilicon spacer and removing the unmasked portion of the polysilicon spacer, removing the mask layer and forming a dielectric layer on the surface of the gate electrodes, the polysilicon spacers and the doping areas, and, using the polysilicon spacer and the substrate as etch stop, etching a portion of the dielectric layer to form a bit line contact.

In this method, the polysilicon spacer may be formed by a conformal polysilicon layer on the surface of the gate electrodes and doping areas and anisotropically etching the polysilicon layer so that the remaining polysilicon layer forms a polysilicon spacer on the sidewalls of the gate electrode.

In the above method, before forming the dielectric layer, a liner layer may be formed on the surface of the gate electrodes, polysilicon spacers and doping areas.

The above objects are further accomplished by a method of forming bit line contact comprising providing a substrate having a plurality of transistors therein, each including a gate electrode and doping areas serving as drain and source, forming a conformal polysilicon layer on the surface of the gate electrodes and doping areas, anisotropically etching the polysilicon layer so that the remaining polysilicon layer forms a polysilicon spacer on the sidewalls of the gate electrode, forming a mask layer on the surface of adjacent gate electrode doping area and a portion of the gate electrode located on both sides of the doping area, removing the mask layer and forming a liner layer overlying the surface of the gate electrodes, polysilicon spacers and doping areas, forming a dielectric layer on the liner layer, using the polysilicon spacer and the doping area as an etch stop, etching a portion of the dielectric layer and the liner layer to form a bit line contact, and filling a conductive layer into the bit line contact to act as a bit line contact plug.

### DESCRIPTION OF THE DRAWINGS

For a better understanding of the present invention, reference is made to a detailed description to act as read in conjunction with the accompanying drawings, in which:

FIG. 1A˜1F are cross sections showing fabrication of the conventional bit line contact.

FIG. 2A˜2I are cross sections of the method of forming a bit line contact according to the present invention.

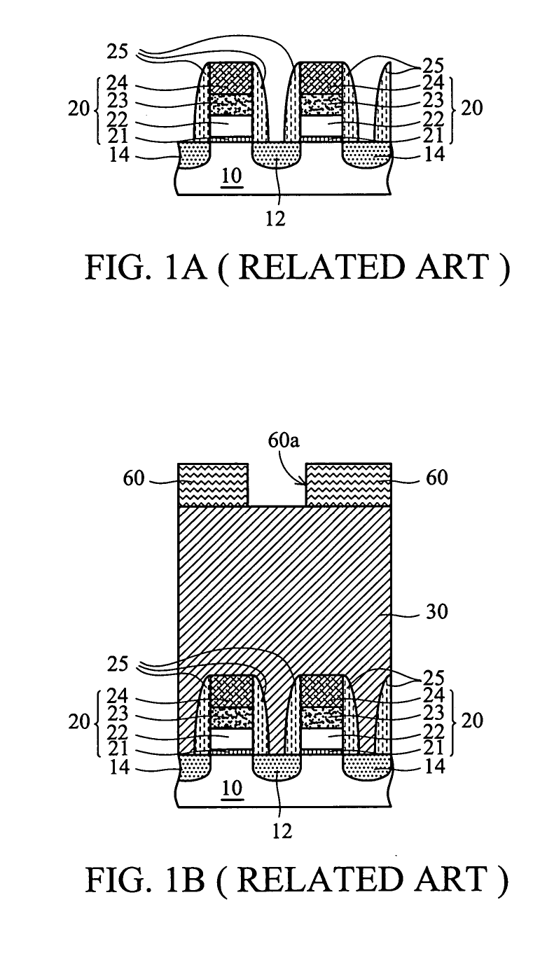

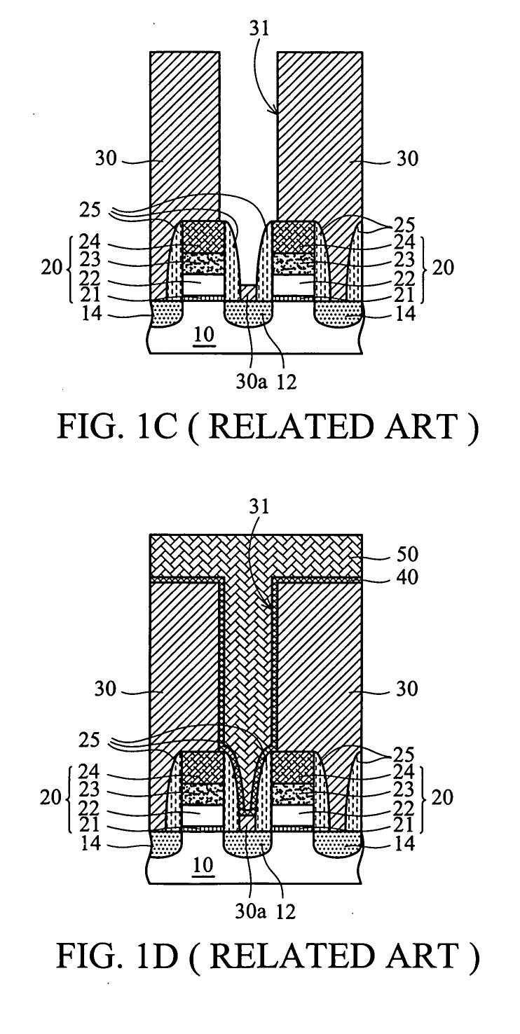

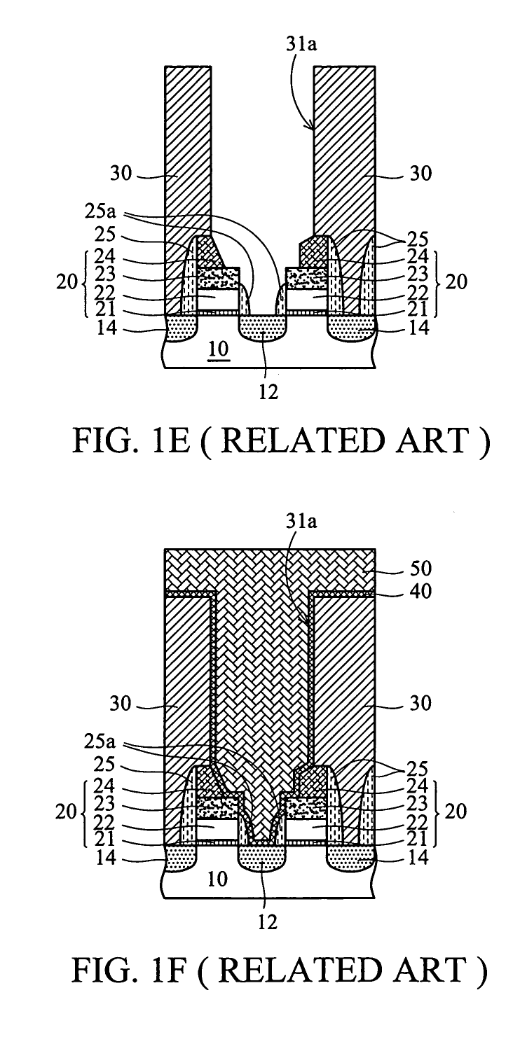

### DETAILED DESCRIPTION OF THE INVENTION

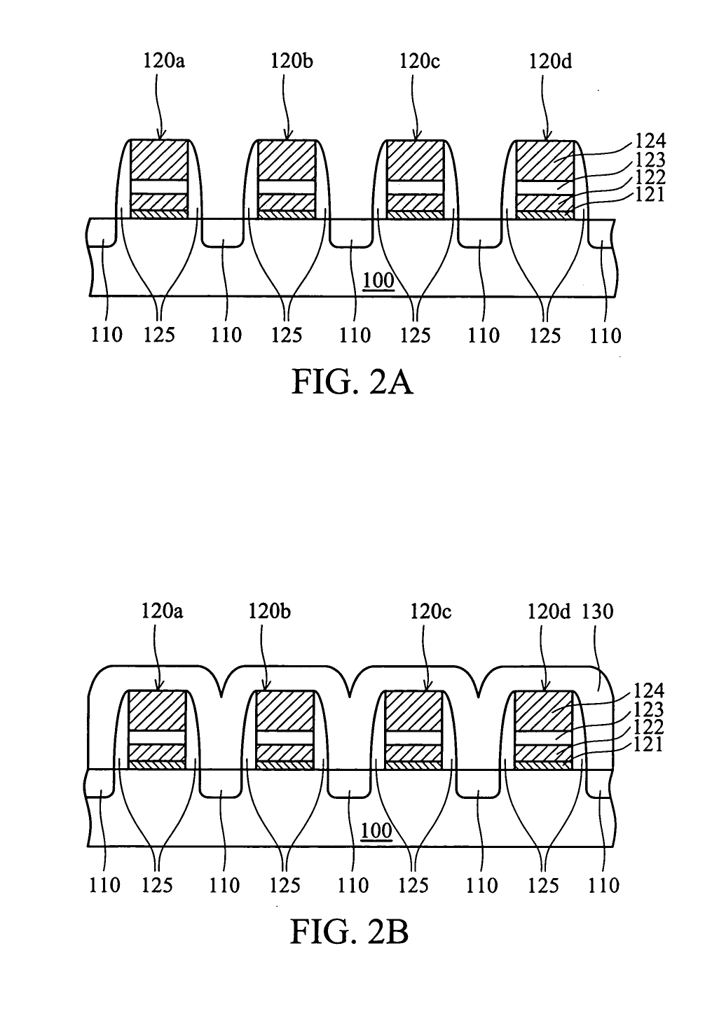

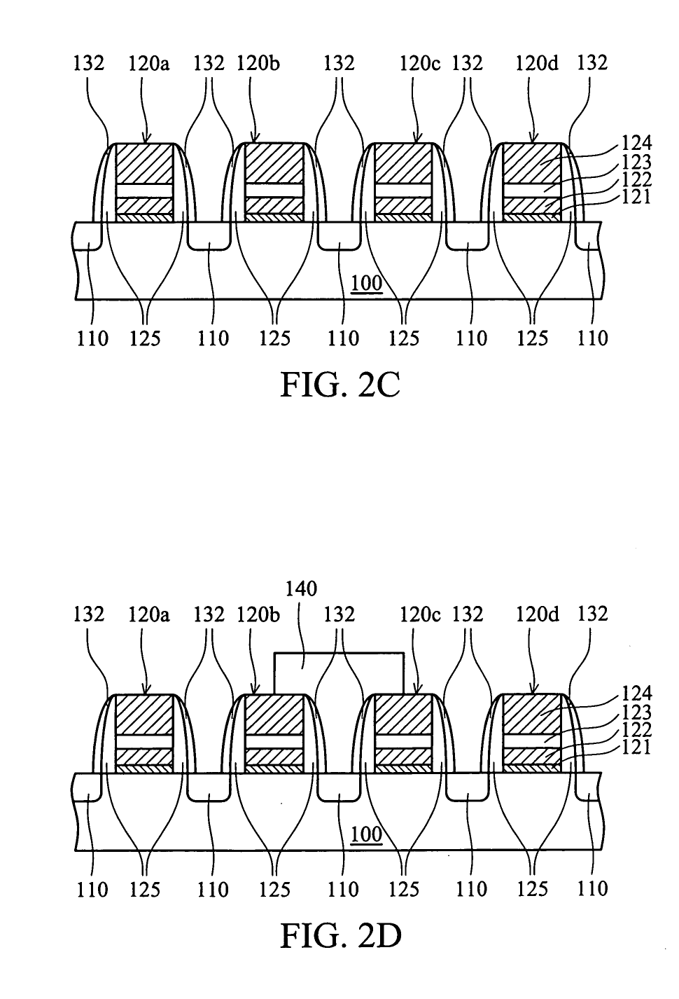

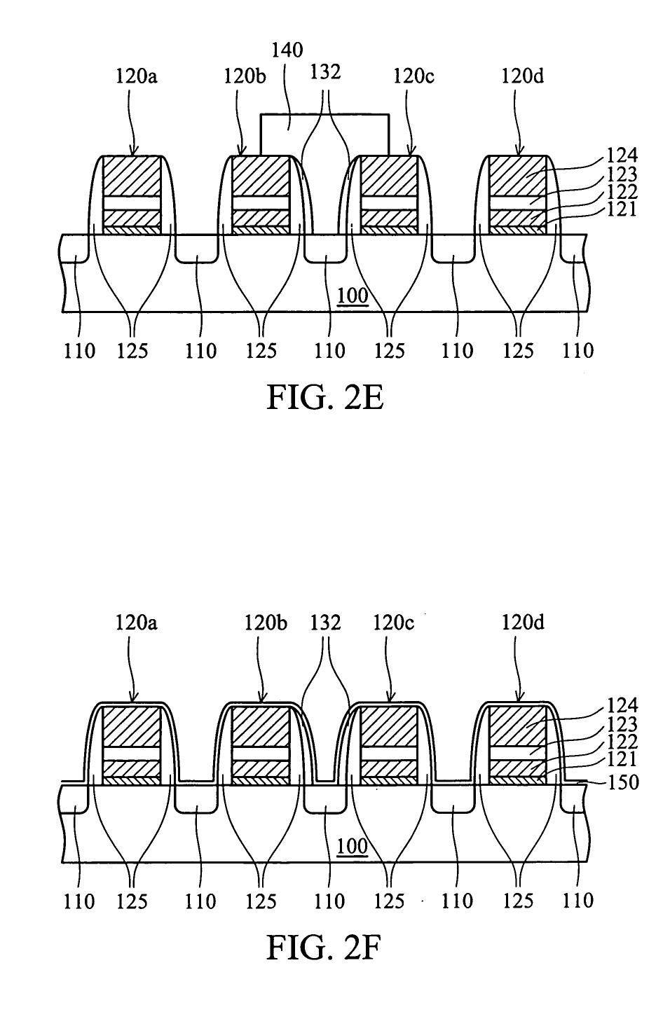

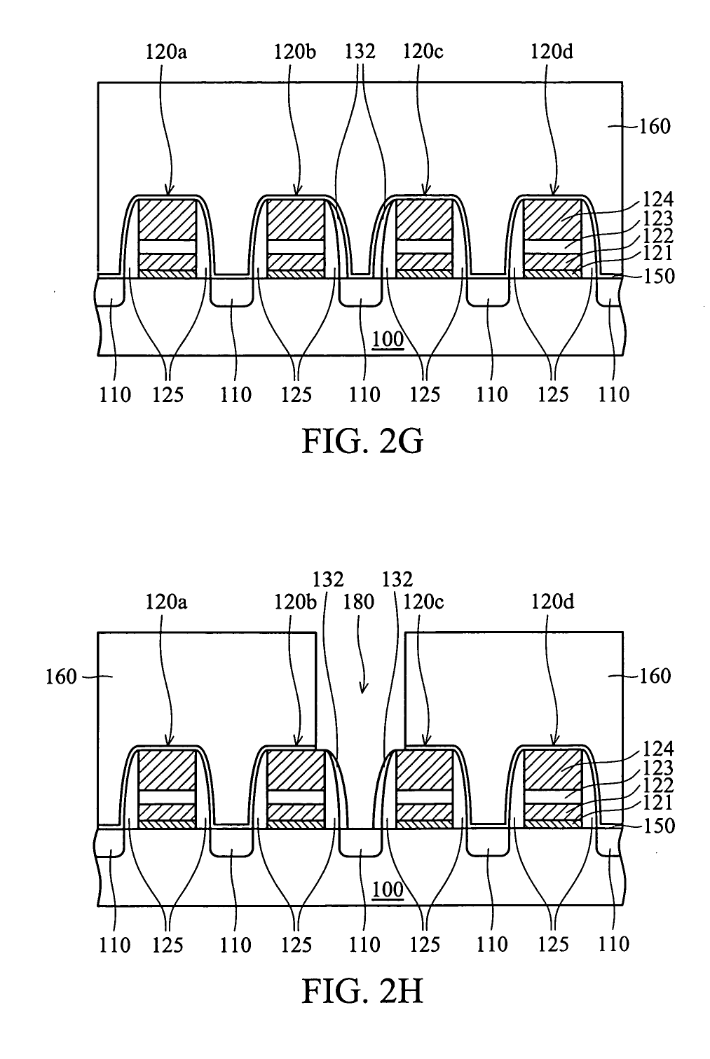

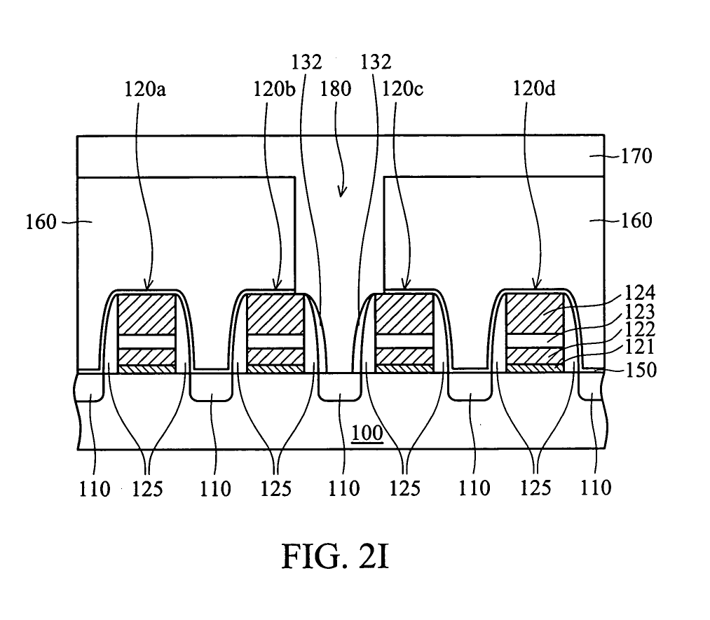

In FIG. 2A, a semiconductor substrate 100, such as a single crystal silicon substrate, is provided with a transistor structure thereon. The active region of the substrate 100 has doping area 110 comprising drain and source areas. Between doping areas 110, gate electrodes 120a˜120d protrude from substrate 100. The gate electrode is a bit line, having multi-layer structure as in the gate electrode 120a˜120d of FIG. 2A, including gate dielectric layer 121, such as an oxide layer, polysilicon layer 122 as a conductive layer, metal silicide layer 123 as a conductive layer, such as Tungsten silicide, and hard mask layer 124, such as a silicon nitride layer. Sidewalls of the gate electrode 120a˜120d have a silicon nitride spacer 125. The gate electrode structures are examples, not intended to limit the scope of the invention.

FIG. 2B shows a barrier layer is formed on the surface of the substrate 100, especially spacers 125, doping areas 110, and gate electrodes 120a˜120d, such that gate electrodes are fully covered. The barrier layer can have barrier properties, such as conductive or semiconductor materials, or comprise combinations thereof, such as polysilicon layer 130, formed by, for example low pressure chemical vapor deposition (LPCVD), with reaction gases of PH3, SiH4 and N2 or AsH3, SiH4 and N2, at between 500-650° C., and ion concentration between 1E20 and 1E21 atom/cm3.

Next, in FIG. 2C, polysilicon layer 130 is etched, forming a polysilicon spacer 132 on the sidewalls of the gate electrode 125, level with gates 120a˜120d. Polysilicon layer 130 can be etched using, for example, magnetic enhanced reactive ion (MERIE), electron cyclotron resonance plasma (ECR) or reactive ion etching (RIE), with gases including, for example, SF6, O2, C12 and HBr.

Next, a portion of the retained polysilicon spacer 132 is formed using photoresist layer 140 as a mask layer. FIG. 2D shows a photoresist pattern layer 140 on the doping area 110 between the gate electrodes 120b and 120c, whereby a portion of the surface of the gate electrodes 120b and 120c is formed. This step masks the polysilicon spacer 132 on both sides of the gate electrodes 120b and 120c in the desired bit line contact position. A photoresist pattern layer 140 is formed to protect the masked polysilicon spacer 132 from removal during subsequent polysilicon spacer 132 etching.

Using the photoresist pattern layer 140 as a mask, the portion of the unmasked polysilicon spacer 132 located on both sides of the gate electrodes 120a and 120d and a portion of electrodes 120b and 120c unmasked by photoresist pattern layer 140 are etched. Then, photoresist pattern layer 140 is removed using solvent or plasma etching, leaving polysilicon spacer 132 between the gate electrodes 120b and 120C. At this point, the high dielectric etching selectivity polysilicon acts as the gate electrode spacer. Wet etching of polysilicon spacer 132, such as BOE or KOH, can remove unmasked polysilicon spacer 132 from photoresist pattern layer 140.

In FIG. 2F, a conformal liner layer 150 is deposited on the substrate surface 100, the gate electrode sidewalls, and the doping areas 110 using, for example, chemical vapor deposition (CVD) with SiON, SiN or SiO2, at thickness from 20 to 200Π. Then, in FIG. 2G, CVD deposits a dielectric layer 160 over liner layer 150. After formation of the dielectric layer 160, dielectric layer 160 can be planarized using CMP or etching back, and unwanted dielectric layer is removed. Dielectric layer 160 can boro-phosphosilicate glass (BPSG), high density plasma chemical vapor deposition (HDPCVD) oxide, oxygen-containing silicate, or combinations thereof.

In FIG. 2H, a photoresist pattern layer on the dielectric layer 160 is formed as an etching mask. Self-aligned contact (SAC) etching is performed using the polysilicon spacer 132, the gate electrode hard mask layer 124, and the substrate 100 as an etch stop. The dielectric layer 160 and the liner layer 150 are etched on the gate electrode 120b and 120c, forming a bit line contact 180. SAC bit line contact can use anisotropic etching, such as magnetic enhanced reactive ion (MERIE), electron cyclotron resonance plasma (ECR), or reactive ion etching (RIE).

The invention provides bit line contact formation using a barrier spacer for the SAC protection layer, for example, polysilicon, having high etching selectivity of 50 or more. With such high etching selectivity, the barrier spacer is not easily removed, and the width of dielectric contact 180 does not increase, such that the portion of the hard mask layer 124 and the sidewall spacer 125 are also not exposed during etching. Thus bit line contact open circuits or bit line/word-line short circuits do not occur when subsequent conductive layer 170 is filled into the bit line contact. Semiconductor process yield is enhanced and process costs are reduced.

Although the present invention has been particularly shown and described above with reference to the preferred embodiment, it is anticipated that alterations and modifications thereof will no doubt become apparent to those skilled in the art. It is therefore intended that the following claims be interpreted as covering all such alteration and modifications as fall within the true spirit and scope of the present invention.

What is claimed is:

1. A method of forming bit line contact comprising the steps of:
providing a substrate having a plurality of transistors therein, each comprising a gate electrode and doping areas serving as drain and source;
forming a polysilicon spacer on the sidewalls of the gate electrodes;
forming a mask layer to cover a portion of the polysilicon spacer, and removing the unmasked portion of the polysilicon spacer;
removing the mask layer and forming a dielectric layer overlying the surface of the gate electrodes, polysilicon spacers and doping areas; and
using the polysilicon spacer and the substrate as an etch stop, etching a portion of the dielectric layer to form a bit line contact.

2. The method of forming bit line contact as claimed in claim 1, wherein formation of a polysilicon spacer on the sidewalls of the gate electrode further comprises:
forming a conformal polysilicon layer on the surface of the gate electrodes and doping areas; and
anisotropically etching the polysilicon layer, such that the remaining polysilicon layer forms a polysilicon spacer on the sidewalls of the gate electrodes.

3. The method of forming bit line contact as claimed in claim 2, wherein the polysilicon layer is formed by low pressure chemical vapor deposition (LPCVD).

4. The method of forming bit line contact as claimed in claim 2, wherein the polysilicon spacer is etched using magnetic enhanced reactive ion (MERIE), electron cyclotron resonance plasma (ECR), or reactive ion etching (RIE).

5. The method of forming bit line contact as claimed in claim 1, wherein the dielectric layer comprises boro-phosphosilicate glass (BPSG), high density plasma chemical vapor deposition (HDPCVD) oxide, oxygen-containing silicate, or combinations thereof.

6. The method of forming bit line contact as claimed in claim 1, wherein the dielectric layer is formed using low pressure chemical vapor deposition (LPCVD), plasma enhanced chemical vapor deposition (PECVD), high density plasma chemical vapor deposition (HDPCVD), atmosphere pressure chemical vapor deposition (APCVD), or second atmosphere pressure chemical vapor deposition (SACVD).

7. The method of forming bit line contact as claimed in claim 1, wherein the gate electrode comprises a cap layer on the top of the gate electrode, and a silicon nitride spacer on the sidewalls of the gate electrode.

8. The method of forming bit line contact as claimed in claim 7, wherein during etching of the unmasked polysilicon spacer, the etching selectivity of the polysilicon spacer to the cap layer of the gate electrode exceeds 50:1.

9. The method of forming bit line contact as claimed in claim 1, further comprising, before forming the dielectric layer, forming a liner layer on the surface of the gate electrodes, polysilicon spacers, and doping areas.

10. The method of forming bit line contact as claimed in claim 9, wherein the liner layer is silicon nitride.

11. The method of forming bit line contact as claimed in claim 9, wherein the dielectric layer and liner layer are etched using magnetic enhanced reactive ion (MERIE), electron cyclotron resonance plasma (ECR), or reactive ion etching (RIE).

12. A method of forming bit line contact comprising the steps of:
providing a substrate having a plurality of transistors therein, each including a gate electrode and doping areas serving as drain and source;
forming a conformal polysilicon layer on the surface of the gate electrodes and doping areas;
etching the polysilicon layer, such that the polysilicon layer forms a polysilicon spacer on the sidewalls of the gate electrodes;
forming a mask layer on the surface of the gate electrode doping area and a portion of the gate electrode located on both sides of the doping area; and removing the unmasked portion of the polysilicon spacer by etching;
removing the mask layer and forming a liner layer overlying the surface of the gate electrodes, the polysilicon spacers and the doping areas;
forming a dielectric layer on the liner layer;
using the polysilicon spacer and the doping area as an etch stop; etching a portion of the dielectric layer and the liner layer to form a bit line contact; and
filling a conductive layer into the bit line contact as a bit line contact plug.

13. The method of forming bit line contact as claimed in claim 12, wherein the polysilicon layer is formed by low pressure chemical vapor deposition (LPCVD).

14. The method of forming bit line contact as claimed in claim 12, wherein the polysilicon spacer is etched using magnetic enhanced reactive ion (MERIE), electron cyclotron resonance plasma (ECR) or reactive ion etching (RIE).

15. The method of forming bit line contact as claimed in claim 12, wherein the dielectric layer comprises boro-phosphosilicate glass (BPSG), high density plasma chemical vapor deposition (HDPCVD) oxide, oxygen-containing silicate, or combinations thereof.

16. The method of forming bit line contact as claimed in claim 12, wherein the dielectric layer is formed using low pressure chemical vapor deposition (LPCVD), plasma enhanced chemical vapor deposition (PECVD), high density plasma chemical vapor deposition (HDPCVD), atmosphere pressure chemical vapor deposition (APCVD), or second atmosphere pressure chemical vapor deposition (SACVD).

17. The method of forming bit line contact as claimed in claim 12, wherein the gate electrode comprises a cap layer on the top of the gate electrode, and a silicon nitride spacer on the sidewalls of the gate electrode.

18. The method of forming bit line contact as claimed in claim 17, wherein during etching of the unmasked polysilicon spacer, etching selectivity of the polysilicon spacer to the cap layer of the gate electrode exceeds 50:1.

19. The method of forming bit line contact as claimed in claim 12, wherein the liner layer is silicon nitride.

20. The method of forming bit line contact as claimed in claim 12, wherein the dielectric layer and liner layer are etched using magnetic enhanced reactive ion (MERIE), electron cyclotron resonance plasma (ECR), or reactive ion etching (RIE).

21. A method of forming bit line contact comprising the steps of:
providing a substrate having a plurality of transistors therein, each including a gate electrode and doping areas serving as drain and source;
forming a pair of barrier spacers on the opposite sidewalls between gate electrodes;
forming a dielectric layer on the surface of the gate electrodes, barrier spacers and doping areas; and
using the barrier spacer and the substrate as an etch stop, etching a portion of the dielectric layer to form a bit-line contact.

22. The method of forming bit line contact as claimed in claim 21, wherein the barrier spacer comprises materials having barrier, conductivity, or semiconducting properties, or combinations thereof.

23. The method of forming bit line contact as claimed in claim 21, wherein during etching of the portion of the dielectric layer, the etching selectivity of the barrier spacer to the dielectric layer exceeds 50:1.

24. The method of forming bit line contact as claimed in claim 21, wherein the dielectric layer comprises boro-phosphosilicate (BPSG), high density plasma chemical vapor deposition (HDPCVD) oxide, oxygen-containing silicate, or combinations thereof.

25. The method of forming bit line contact as claimed in claim 12, wherein the dielectric layer is formed by low pressure chemical vapor deposition (LPCVD), plasma enhanced chemical vapor deposition (PECVD), high density plasma chemical vapor deposition (HDPCVD), atmosphere pressure chemical vapor deposition (APCVD), or second atmosphere pressure chemical vapor deposition (SACVD).

26. The method of forming bit line contact as claimed in claim 21, wherein the gate electrode comprises a cap layer on the top of the gate electrode, and a silicon nitride spacer on the sidewalls of the gate electrode.

27. The method of forming bit line contact as claimed in claim 21, further comprising, before forming the dielectric layer, forming a liner layer on the surface of the gate electrodes, barrier spacers, and doping areas.

28. The method of forming bit line contact as claimed in claim 27, wherein the liner layer is silicon nitride.
